(19) United States
(12) Patent Application Publication
(10) Pub. No.: US 2014/0102498 A1
(43) Pub. Date: Apr. 17, 2014

(54) Methods of Fabricating Thermoelectric Elements

(71) Applicant: GMZ Energy, Inc., Waltham, MA (US)

(72) Inventors: Bed Poudel, Brighton, MA (US); Giri Joshi, Maynard, MA (US); Jian Yang, Waltham, MA (US); Tej Panta, Waltham, MA (US); James Christopher Caylor, Melrose, MA (US); Jonathan D'Angelo, Somerville, MA (US); Zhifeng Ren, Newton, MA (US)

(73) Assignee: GMZ Energy, Inc., Waltham, MA (US)

(21) Appl. No.: 14/049,380

(22) Filed: Oct. 9, 2013

Related U.S. Application Data
(60) Provisional application No. 61/712,633, filed on Oct. 11, 2012.

(51) Int. Cl. H01L 35/34; H01L 35/12

(52) U.S. Cl. CPC H01L 35/34; H01L 35/12
USPC 136/200; 438/54

(57) ABSTRACT

Methods of fabricating a thermoelectric element with reduced yield loss include forming a solid body of thermoelectric material having first dimension of 150 mm or more and thickness dimension of 5 mm or less, and dicing the body into a plurality of thermoelectric legs, without cutting along the thickness dimension of the body. Further methods include providing a metal material over a surface of a thermoelectric material, and hot pressing the metal material and the thermoelectric material to form a solid body having a contact metal layer and a thermoelectric material layer.

### RELATED APPLICATION

This application claims the benefit of priority to U.S. Provisional Application No. 61/712,633, filed Oct. 11, 2012, the entire contents of which are incorporated herein by reference.

### BACKGROUND

Devices for cooling and power generation based on thermoelectric effects are known in the art. Solid-state devices that employ the Seebeck effect or Peltier effect for power generation and heat pumping are known. For power generation, for example, a thermoelectric converter relies on the Seebeck effect to convert temperature differences into electricity. A thermoelectric generator (TEG) module includes a first (hot) side, a second (cold) side, and a plurality of thermoelectric converters disposed there between (e.g., pairs of p-type and n-type legs of thermoelectric material). Electrically conductive leads may provide appropriate electrical coupling within and/or between thermoelectric converters, and may be used to extract electrical energy generated by the converters.

### SUMMARY

Embodiments include a method of fabricating a thermoelectric element that comprises forming a solid body comprising thermoelectric material having first dimension of 150 mm or more and thickness dimension of 5 mm or less, and dicing the body into a plurality of thermoelectric legs, without cutting along the thickness dimension of the body.

Further embodiments include a solid body comprising thermoelectric material having a first dimension of 150 mm or more and a thickness dimension of 5 mm or less, wherein the solid body is formed by hot pressing particles of thermoelectric material.

Further embodiments include a method of fabricating a thermoelectric element that comprises providing a metal material over a surface of a thermoelectric material, and hot pressing the metal material and the thermoelectric material to form a solid body having a contact metal layer and the thermoelectric material.

Further embodiments include a thermoelectric element that comprises a thermoelectric material layer; a contact metal layer comprising a metal material over the thermoelectric material layer, preferably having a thickness of 0.05 to 1 mm, and an interlayer preferably having a thickness of 1 to 100 μm between the first contact metal layer and the thermoelectric material layer, wherein the first interlayer comprises the metal material and at least one constituent of the thermoelectric material.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a schematic perspective view of a wafer of thermoelectric material that is diced to provide a plurality of thermoelectric elements.

FIG. 2 is a process flow diagram illustrating an embodiment method for fabricating a thermoelectric device.

FIG. 3 schematically illustrates a prior art method of fabricating a thermoelectric device having contact metal layers.

FIG. 4 schematically illustrates an embodiment method of fabricating a thermoelectric device in which contact metal layers are hot pressed onto a thermoelectric material.

FIG. 5 is a scanning electron microscope (SEM) image of a BiTe-based thermoelectric device having nickel contact layers formed by hot pressing.

FIG. 6 schematically illustrates an experimental setup for testing the contact resistance of various thermoelectric devices.

FIG. 7 is a plot of voltage (which is proportional to contact resistance) vs. distance for a p-type BiTe thermoelectric element having nickel contact layers fabricated in accordance with an embodiment method.

FIGS. 8A-8D are SEM images (FIGS. 8A-8B) and energy dispersive spectroscopy (EDS) plots (FIGS. 8C-8D) of a p-type BiTe thermoelectric element having nickel contact layers formed by hot pressing.

FIG. 9 is a plot of voltage vs. distance for an n-type BiTe thermoelectric element having nickel contact layers formed by hot pressing.

FIGS. 10A-10D are SEM images (FIGS. 10A-10B) and EDS plots (FIGS. 10C-10D) of an n-type BiTe thermoelectric element having nickel contact layers formed by hot pressing.

FIGS. 11A and 11B are plots showing the percent change in contact resistance and device efficiency over time for a group of comparative devices having contact metal layers formed by conventional methods (FIG. 11A) and embodiment devices having contact metal layers formed by hot pressing (FIG. 11B).

FIGS. 12A and 12B are plots showing the percent change in contact resistance and device efficiency over time for a group of embodiment devices having contact metal layers formed by hot pressing (FIG. 12A) and a group of commercially-available comparative devices having contact metal layers formed by thermal spray (FIG. 12B).

FIG. 13 is a plot of voltage vs. distance for an n-type half-Heusler thermoelectric element having titanium contact layers formed by hot pressing.

FIG. 14A is a SEM image of an n-type half-Heusler thermoelectric element having titanium contact layers formed by hot pressing.

FIG. 14B is an EDS plot for the n-type half-Heusler thermoelectric element having titanium contact layers formed by hot pressing.

FIG. 14C is a magnified SEM image with an EDS spectra overlay for the n-type half-Heusler thermoelectric element having titanium contact layers formed by hot pressing.

FIGS. 15A-15C are SEM images of a thermoelectric element having an interlayer between an n-type half-Heusler material and a titanium contact layer.

FIG. 16 is a plot of voltage vs. distance for a p-type half-Heusler thermoelectric element having titanium contact layers formed by hot pressing.

FIG. 17A is a SEM image of a p-type half-Heusler thermoelectric element having titanium contact layers formed by hot pressing.

FIG. 17B is an EDS plot for the p-type half-Heusler thermoelectric element having titanium contact layers formed by hot pressing.

FIG. 17C is a magnified SEM image with an EDS spectra overlay for the p-type half-Heusler thermoelectric element having titanium contact layers formed by hot pressing.

FIGS. 18A-18C are SEM images of a thermoelectric element having an interlayer between a p-type half-Heusler material and a titanium contact layer.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Various embodiments include methods of fabricating thermoelectric elements, as well as thermoelectric elements manufactured in accordance with the embodiment methods.

In thermoelectric power generation and cooling, bulk thermoelectric materials may be fabricated into discrete elements, such as posts or “legs.” A thermoelectric device for power generation or cooling may comprise plural sets of two thermoelectric elements—one p-type and one n-type semiconductor converter post or leg which are electrically connected to form a p-n junction. For electricity generation, the thermoelectric converter materials can comprise, but are not limited to, one of: Bi₂Te₃, Bi₂Te₃₋ₓSeₓ (n-type)/BiₓSe₂₋ₓTe₃ (p-type), SiGe (e.g., Si₈₀Ge₂₀), PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, half-Heusler materials (e.g., Hf_{1+d-x-y}ZrₓTi_{y}NiSn_{1+d-z} Sb_{z}, where 0≦x≦1.0, 0≦y≦1.0, 0≦z≦1.0, and −0.1≦d≦0.1, such as Hf_{1-x-y}ZrₓTi_{y}NiSn_{1-z}Sb_{z}, where 0≦x≦1.0, 0≦y≦1.0, and 0≦z≦1.0 when d=0, and/or Hf_{1+d-x-y}ZrₓTi_{y}CoSb_{1+d-z}Sn_{z}, where 0≦x≦1.0, 0≦y≦1.0, 0≦z≦1.0, and −0.1≦d≦0, such as Hf_{1-x-y}ZrₓTi_{y}CoSb_{1-z}Sn_{z}, where 0≦x≦1.0, 0≦y≦1.0, and 0≦z≦1.0 when d=0) and combinations thereof. The materials may comprise compacted nanoparticles or nanoparticles embedded in a bulk matrix material. For example, such materials are described in U.S. patent application Ser. No. 11/949,353 filed Dec. 3, 2007, incorporated herein by reference in its entirety.

In a conventional method for fabricating thermoelectric elements, bulk thermoelectric material is formed into a solid body, such as a disk, via an ingot growth technique. Alternatively, the bulk thermoelectric material may be in the form of small particles (e.g., powder). The particles, which may be nano-sized and/or micro-sized, are then consolidated (i.e., densified) to form a thick solid disk or slab having a thickness of 10 mm or more, such as 100-500 mm, using a hot-press or similar compaction process. As used herein, a “nanoparticle” or “nano-sized” structure, generally refers to material portions, such as particles, whose dimensions are less than 1 micron, preferably less than about 100 nanometers. For example, nanoparticles may have an average cross-sectional diameter in a range of about 1 nanometer to about 0.1 micron, such as 10-100 nm. A “microparticle” or “micro-sized” structure generally refers to material portions, such as particles, whose dimensions are less than about 100 micron. For example, microparticles may have an average cross-sectional diameter in a range of about 1 to 100 microns.

In either of the conventional fabrication methods, the solid disk of thermoelectric material must then undergo further processing to produce a thermoelectric element (i.e., a “leg”) having the desired size and shape. Typically, the disk is sliced along its thickness dimension to form a plurality of thin (e.g., 0.5 to 5 mm thick) wafers. The disk may be sliced to provide a wafer having a thickness dimension equal to the thickness of the finished thermoelectric element. The wafer is then diced along its length and width dimensions to produce the thermoelectric elements, which are typically in the millimeter size range.

The process of slicing the thermoelectric material disk through its thickness dimension for form wafers results in unavoidable yield losses. Each cut through the thickness dimension of the disk results in a loss of approximately 0.2 mm of the thermoelectric material. This is known as “kerf” loss, and can result in significant yield loss of the thermoelectric material. Further losses occur when the thermoelectric material disk is diced into individual thermoelectric element, particularly along the edges of the disk (i.e., edge loss). Overall yield losses may be approximately 9%.

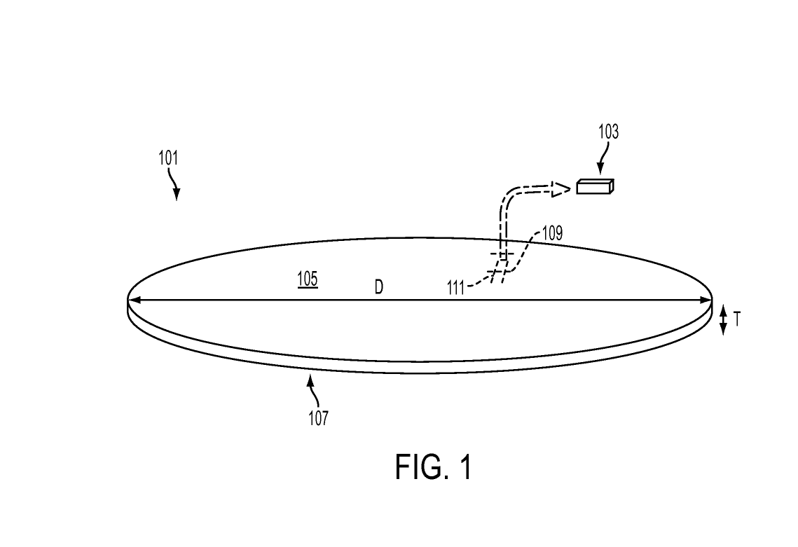

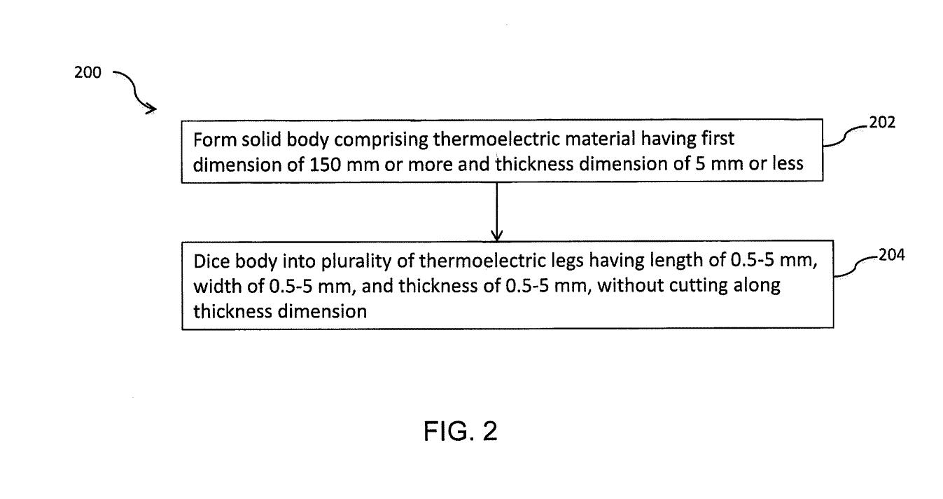

Various embodiments relate to methods of fabricating thermoelectric elements with reduced yield losses. FIG. 1 illustrates a thermoelectric material solid body 101 and thermoelectric element 103 according to one embodiment. FIG. 2 is a process flow diagram illustrating an embodiment method 200 for fabricating a thermoelectric element. In step 202 of embodiment method 200, a thermoelectric material is formed into solid body having first dimension of 150 mm or more (e.g., 150-450 mm, such as 200-300 mm) and a thickness dimension of 5 mm or less. The first dimension may be a length or width dimension. For example, when the solid body 101 has a circular shape (e.g., a disc wafer) such as shown in FIG. 1, the first dimension is the diameter, D, of the body 101. The thickness dimension of 5 mm or less (e.g., 0.5 to 5 mm) may be substantially equal to the final thickness of the thermoelectric elements 103 produced from the solid body 101 (i.e., thermoelectric material wafer).

In various embodiments, the solid body 101 may be formed by compacting particles of semiconductor thermoelectric material. The particles may be, for example, a powder comprising nano-sized and/or micro-sized particles. The particles may be consolidated to form the solid body 101 by hot pressing (i.e., simultaneous application of elevated pressure and temperature). The solid body 101 may have contact layers of a metal material (e.g., nickel, titanium, etc.) extending over the major surfaces 105, 107 of the body 101. As described in further detail below, the contact metal layers may be adhered to the thermoelectric material at the same time that the thermoelectric material is consolidated, such as by hot pressing metal powder or metal foil layers to nano-sized and/or microsized thermoelectric material particles.

In step 204 of embodiment method 200, the solid body 101 of thermoelectric material, which may optionally include contact metal layer(s) is diced into a plurality of thermoelectric elements 103 (i.e., legs) without cutting through the thickness dimension of the body 101 (i.e., without dicing parallel to surface 105 and 107 planes). This is schematically illustrated in FIG. 1 by the dashed lines 109, 111 indicating a plurality of parallel and transverse cuts that may be made to separate the body 101 into a plurality of thermoelectric elements, such as element 103. In this embodiment, no cuts are made along the thickness dimension (T) of the body 101. In various embodiments, the length and width dimensions of each element 103 may each be between about 0.5 and 5 mm. The thickness dimension of the element 103 may be determined by the thickness of the solid body 101 from which the element 103 was separated, and may be between about 0.5 and 5 mm.

By forming the solid body 101 into a shape having a thickness dimension that is the same as the thickness of the finished thermoelectric element, no cuts need to be made along the thickness of the body 101 and kerf losses may be avoided. Furthermore, the large diameter of the solid body 101 (e.g., 150 mm or more) minimizes the edge loss when the body is diced into individual elements. Total losses may be approximately 1% or less of the thermoelectric material. Losses may be further minimized when the solid body 101 is formed with a square or rectilinear shape when viewed from the top (i.e., normal to surface 105) instead of the circular wafer shape shown in FIG. 1.

Further embodiments include methods for depositing contact metal layer(s) on thermoelectric materials to fabricate a thermoelectric device. One or more metal layers may be hot pressed directly onto the thermoelectric material during powder consolidation, thus eliminating a separate metallization step. This method may be used for a variety of thermoelectric materials, such as Bismuth Telluride based alloys and half-Heusler alloys. In embodiments, the method allows deposition of thick metal contact layers on the thermoelectric materials, which may be needed for electrode joining and to prevent metal diffusion into the thermoelectric materials. In addition, the metal contact layer may have very strong shear and tensile strength. Conventional methods for forming thick metal layers, such as thermal spray, sputtering and plating, provide inferior adhesion strength to nano/micro-structured thermoelectric alloys formed by hot pressing nano or micro sized powders. In various embodiments, the present method provides a solution to make modules (both power generation and cooling) from nano/micro-structured thermoelectric materials which have high adhesion strength and thick metal contact layers.

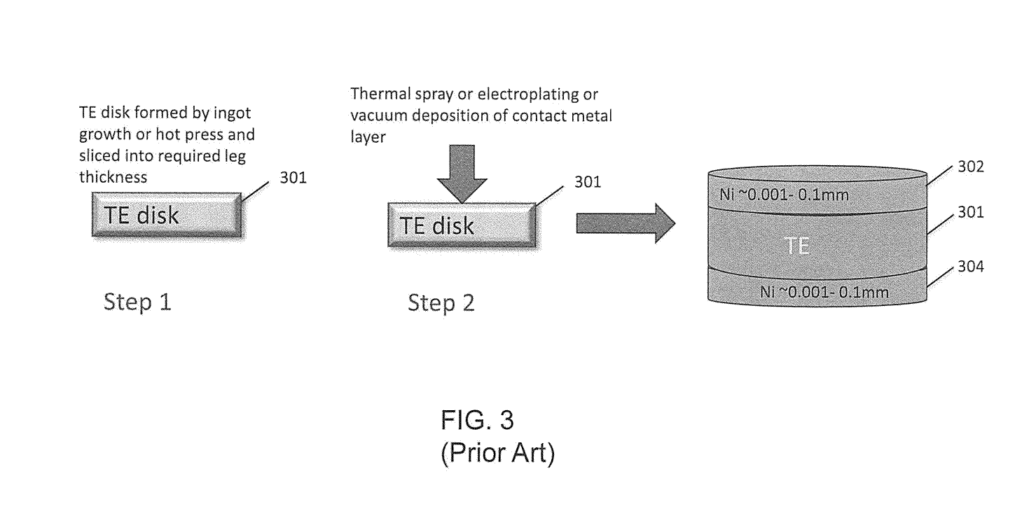

In conventional methods for contact metallization, a thermoelectric material is formed into a solid body, such as a disk 301 as shown in FIG. 3, having a desired size and shape. The disk may be formed by a known technique, such as via ingot growth or by hot pressing of nano-/micro-structured thermoelectric materials, and is then sliced into the desired leg thickness, such as shown in FIG. 3. Contact metal layers 302, 304 are formed on the surfaces of the TE disk via thermal spray, electroplating, or vacuum deposition (e.g., sputtering) to form the TE element 306 shown in FIG. 3. The metal layers (e.g., Ni) typically have a thickness of 0.001-0.1 mm. When the metal layer is deposited by electroplating, the thickness is limited to ˜10 microns. Thermal spray enables deposition of metal layers with thickness up to about 100 microns, but cannot be applied to nano/micro-structured thermoelectric materials with sufficient adhesion strength. Vacuum deposition is a more expensive process that deposits metal layers having a thickness of only a few microns. In the conventional methods, the typical metal contact adhesion strength is on the order of 10 MPa (e.g., less than 15 MPa).

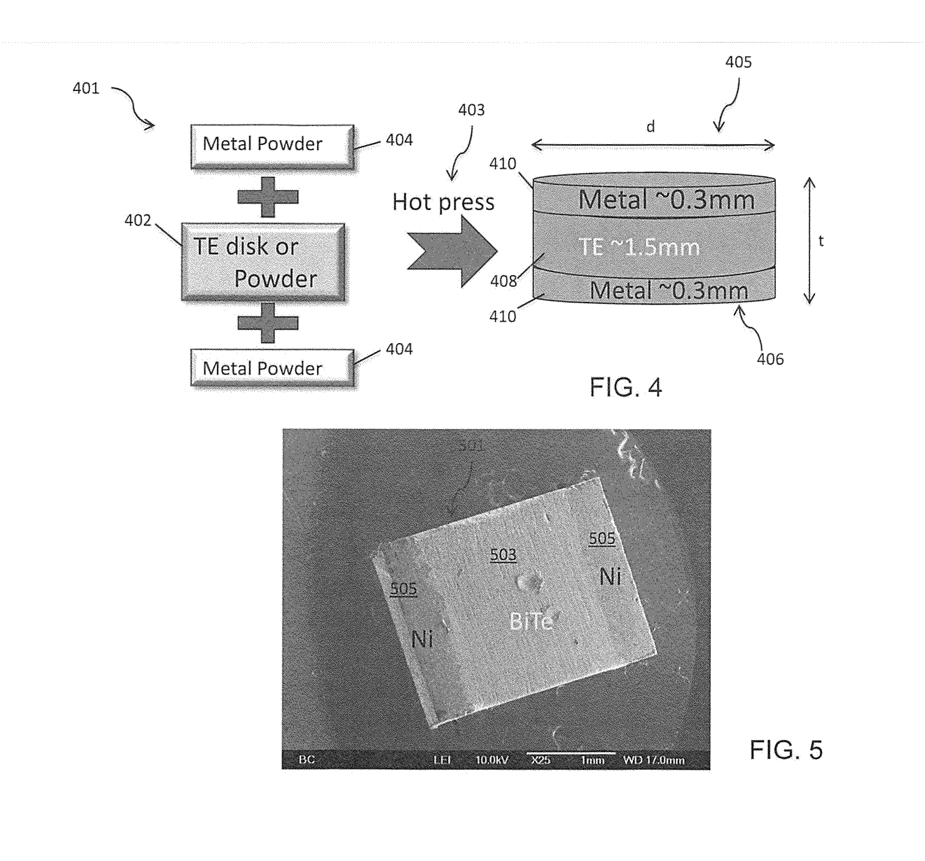

FIG. 4A schematically illustrates a method 400 of fabricating a thermoelectric device in which contact metal layer(s) are hot pressed directly onto the thermoelectric material according to an embodiment. As shown in step 401 of FIG. 4A, a thermoelectric material 402 is provided. In embodiments, the thermoelectric material 402 may be particles (e.g., a powder) of one or more suitable thermoelectric materials (e.g., p-type or n-type BiTe or half-Heusler materials, etc.). In various embodiments, the particles may be nano-sized and/or micro-sized particles. The particles may be loaded into a die cavity of a suitable hot press apparatus (not shown). A metal material 404 may be provided over and/or under one or more surfaces of the thermoelectric material 402. The metal material may be a metal powder, (e.g., a millimeter sized, micro-sized and/or nano-sized powder), or a metal foil, for example.

The combined thermoelectric and metal materials 402, 404 may then undergo a hot pressing treatment (i.e., simultaneous application of elevated pressure and temperature) as shown in step 403. The hot pressing treatment may consolidate and densify the particles to produce a solid body 406 in a desired size and shape. In one embodiment, the hot pressing may have a peak temperature in a range of 250-1500° C. and a pressure of 10-200 MPa. In some embodiments, such as for hot pressing BiTe-based thermoelectric materials, the peak temperature may be in a range of 300-550° C. In other embodiments, such as for hot pressing half-Heusler-based thermoelectric materials, the peak temperature may be in a range of 800-1200° C. The duration of the hot press step may be 30 seconds to 2 hours, such as between about 1 and 30 minutes (not including ramping times).

The hot pressing treatment produces a solid body 406 (e.g., a wafer, slab or disk) having contact metal layer(s) 410 over two sides of a thermoelectric material layer 408, as shown in step 405. FIG. 5 is a scanning electron microscope (SEM) image of a BiTe-based thermoelectric device 501 having Ni contact layers 505 formed on a thermoelectric material 503 by hot pressing. In embodiments where the thermoelectric material is a powder, the hot pressing step may be used both to consolidate (e.g., densify) the thermoelectric powder as well as to apply contact metal layers in a single, cost-effective step. In other embodiments, the thermoelectric material may be previously formed into a solid body (e.g., a disk), and the hot pressing step may be used to adhere metal contact layers to the body.

In embodiments, the hot pressing step may press the thermoelectric 402 and metal 404 materials to a thickness, t, that corresponds to the thickness of the fully-fabricated thermoelectric elements (i.e., legs). A typical thickness is 0.5-5 mm. Pressing the materials to the final device thickness may eliminate kerf loss, as discussed above. The diameter (or width for non-cylindrical bodies), d, of the disk 406 may be any suitable size, e.g., from ˜1 mm to any arbitrary size, such as 150-300 mm, for example. The disk 406 may be diced to form TE legs having desired dimensions (e.g., thickness of 0.5-5 mm, width of 0.5-5 mm, and length of 0.5-5 mm).

The thickness of the thermoelectric material layer 408 may be 0.5-5 mm, such as 1.5-2 mm. The thickness of the metal layers 406 may be 0.05-1 mm, such as 0.3-0.5 mm. A thick metal layer (e.g., greater than 0.1 mm, such as 0.1 to 1 mm, e.g., 0.5 to 1 mm) may enable the layers 410 to be joined to another structure or surface, such as an electrode, by welding. A thick metal layer may be important in high temperature operation. If the contact layer is too thin, diffusion of solder or electrode material into the TE material may ruin the performance of the device. Furthermore, a thick contact layer may enable an electrode to be welded to the contact layer without soldering or brazing.

In various embodiments, the hot pressing step is performed such that an interlayer is formed between the contact metal layer and the thermoelectric material. The interlayer may be a multiphase layer that has a composition that includes the metal of the contact layer and at least one component of thermoelectric material. The interlayer may have a thickness of 1-100 μm.

The interlayer may improve the adhesion strength, including tensile and shear strength, of the contact metal layer on the thermoelectric material. In embodiments, the adhesive strength of the contact metal layer on the thermoelectric material may be greater than 10 MPa, such as 12 MPa or more (e.g., 15-35 MPa). The interlayer may further help to achieve very low contact resistance and improved thermal cycling and stability during operation. The contact resistance of a thermoelectric element produced in accordance with the present hot press method may be less than 15 μΩ-cm², such as 10 μΩ-cm² or less (e.g., 1-5 μΩ-cm², such as 1-2 μΩ-cm²).

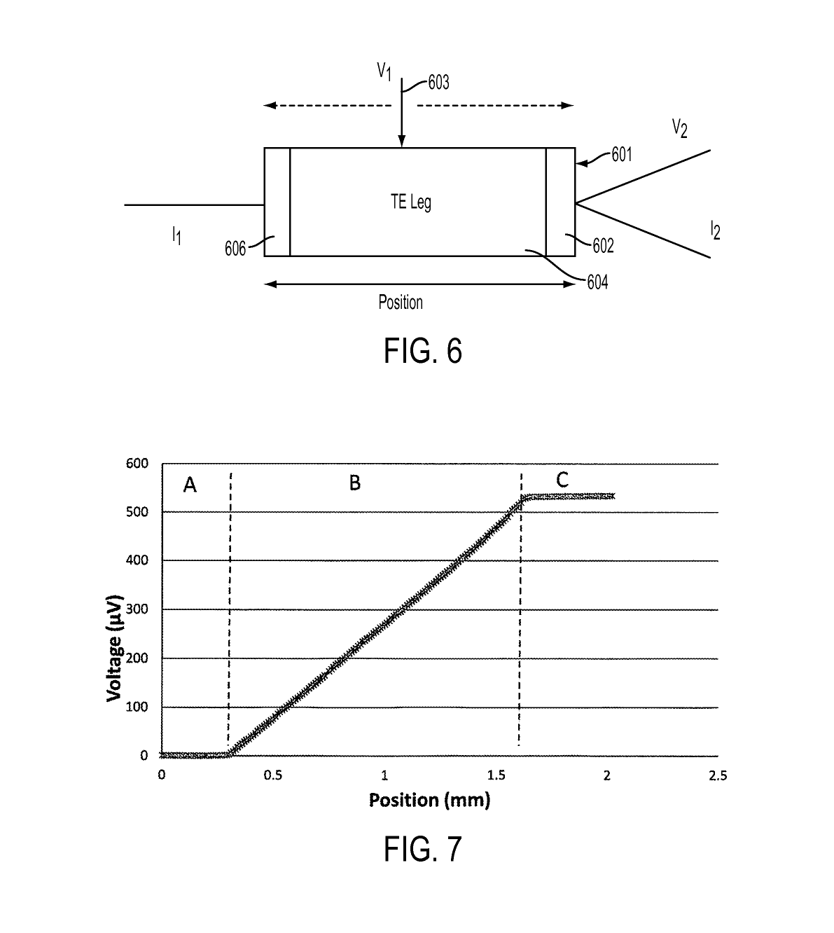

FIG. 6 schematically illustrates an experimental setup for testing the contact resistance of various TE devices (legs) formed by the hot pressing method as described above. A current is provided through the TE device 601 via current leads, I₁ and I₂, and the voltage drop across sensing terminals, V₁ and V₂, is measured as one of the sensing terminals (e.g., probe 603) is moved to different positions along the length of the element 601 (e.g., from a first contact metal layer 602, along the TE material 604, to a second contact metal layer 606), as indicated by the dashed arrows. The voltage measured by the probe 603 is proportional to the resistance of the element 601, and may be used to determine the contact resistance of the device 601.

FIG. 7 is a plot of voltage (which corresponds to contact resistance) vs. distance for a p-type BiTe thermoelectric element having nickel contact layers formed by hot pressing. In the plot, Region A (0 to ˜0.3 mm) corresponds to a first nickel contact layer, Region B (˜0.3 to ˜1.6 mm) corresponds to the p-type BiTe layer, and Region C (˜1.6 to ˜2.0 mm) corresponds to the second nickel contact layer. It is noted that the plot of measured voltage (which are proportional to resistance) includes substantially no gap in the transition between Region A and Region B, as well as substantially no gap in the transition between Regions B and C. This indicates that the contact resistance of the device is low (e.g., ˜2 μΩ-cm²). In this example, the tensile strength of the Ni contact layer on the p-type BiTe thermoelectric material was ˜30 MPa.

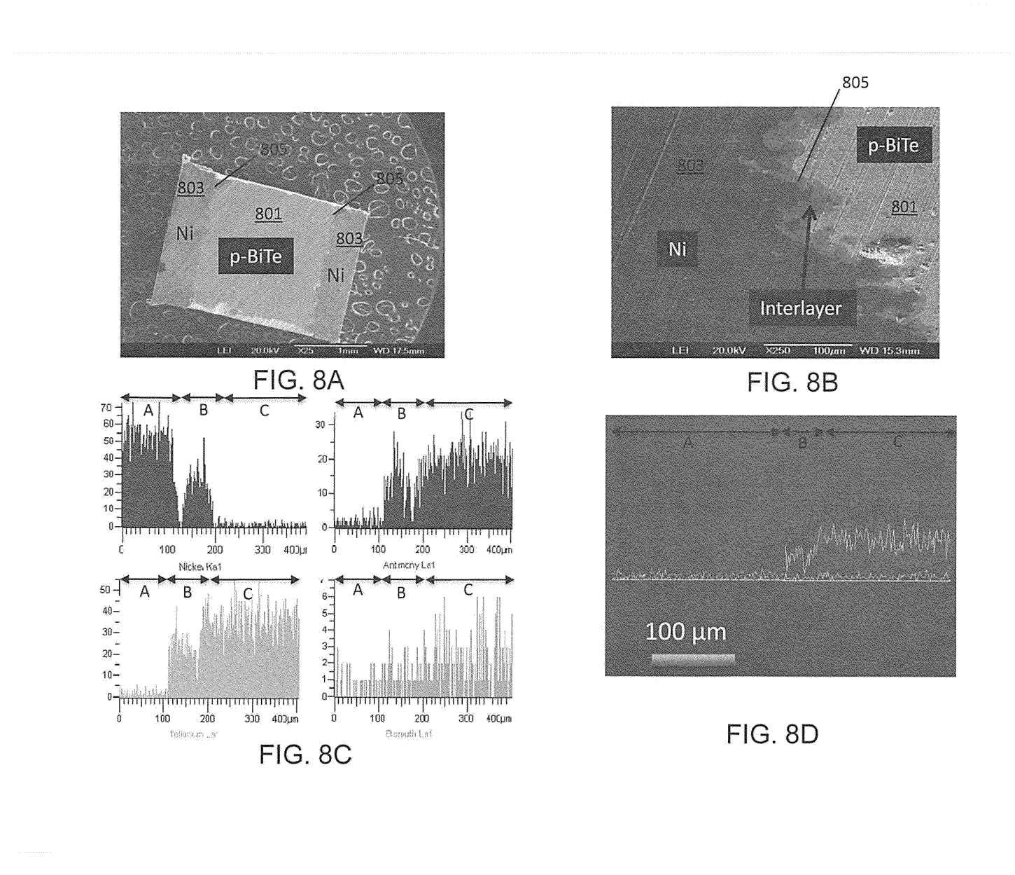

FIGS. 8A-8D are SEM images (FIGS. 8A-8B) and energy-dispersive spectroscopy (EDS) plots (FIGS. 8C-8D) of a p-type BiTe (e.g., Sb doped Bi₂Te₃) thermoelectric element having nickel contact layers formed by hot pressing, as discussed above. An interlayer 805 is visible between the p-BiTe thermoelectric material 801 and the Ni contact layers 803 in FIGS. 8A-8B. The interlayer 805 corresponds to Region B in the EDS plots of FIGS. 8C-8D, while the nickel contact layer 803 and the p-type BiTe thermoelectric material layer 801 correspond to Regions A and C, respectively. The EDS plots indicate that the interlayer 805 in this example has a thickness of about 50 μm and contains nickel and at least one constituent of the thermoelectric material (i.e., bismuth, tellurium and/or antimony in this example). Further, the interlayer 805 acts as a barrier layer such that metal material from the contact layer 803 is inhibited from diffusing into the thermoelectric layer 801. As shown in FIG. 8C-8D, for example, Region C, corresponding to the thermoelectric material layer 801, is substantially free of nickel.

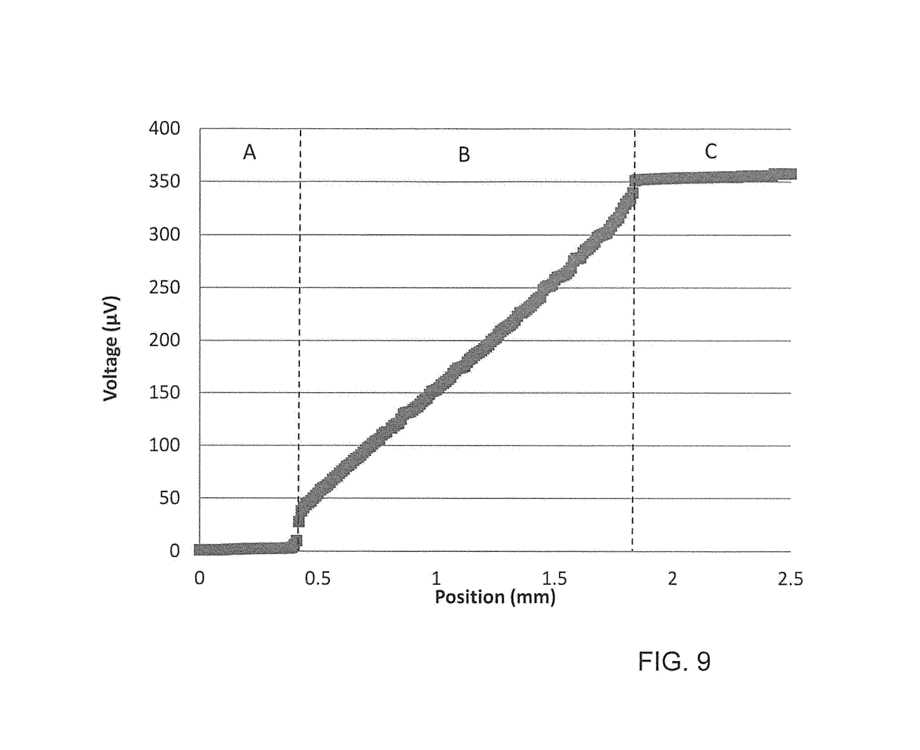

FIG. 9 is a plot of voltage vs. distance for an n-type BiTe (e.g., Se doped Bi₂Te₃) thermoelectric element having nickel contact layers formed by hot pressing. In the plot, Region A (0 to ˜0.4 mm) corresponds to a first nickel contact layer, Region B (˜0.4 to ˜1.8 mm) corresponds to the n-type BiTe layer, and Region C (˜1.8 to ˜2.5 mm) corresponds to the second nickel contact layer. In this example, the small gaps in the transitions between Regions A and B and Regions B and C indicate that the device has a contact resistance of ˜10 μΩ-cm². In this example, the tensile strength of the Ni contact layer on the n-type BiTe thermoelectric material was ˜17 MPa.

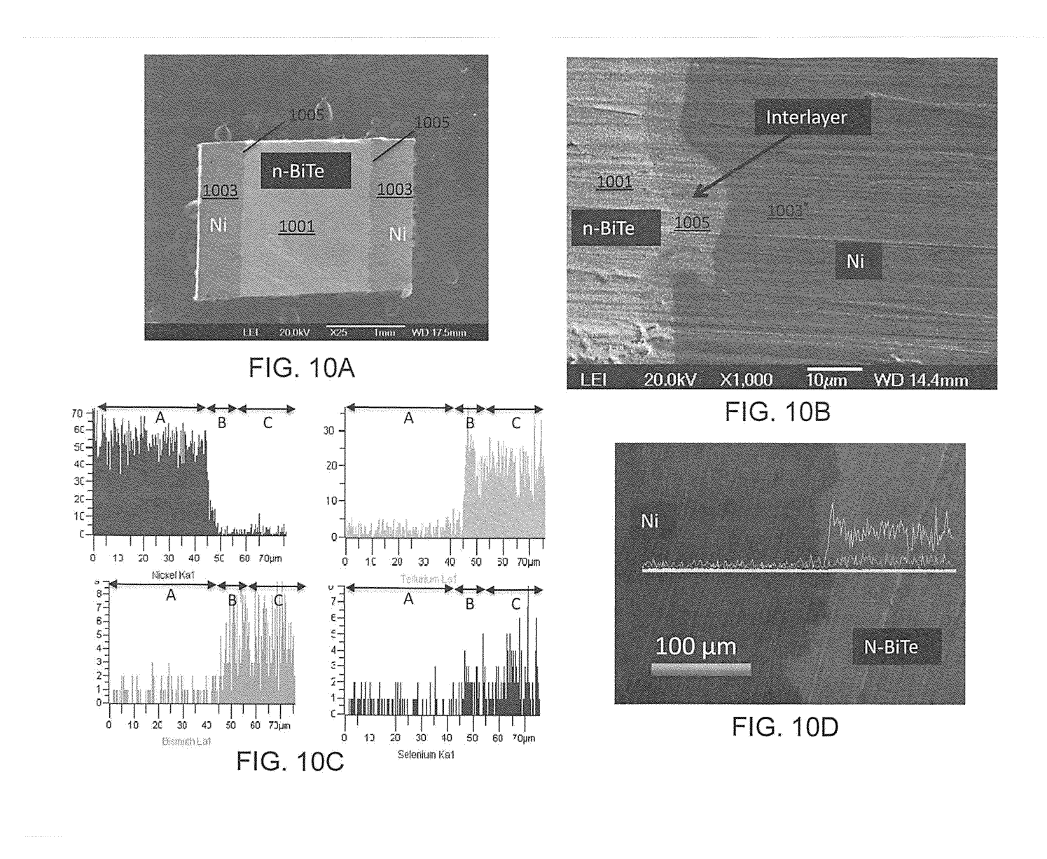

FIGS. 10A-10D are SEM images (FIGS. 10A-10B) and EDS plots (FIGS. 10C-10D) of an n-type BiTe thermoelectric element having nickel contact layers formed by hot pressing, as discussed above. An interlayer 1005 is visible between the n-BiTe thermoelectric material 1001 and the Ni contact layers 1003 in FIGS. 8A-8B. The interlayer 1005 corresponds to Region B in the EDS plots of FIGS. 10C-10D, while the nickel contact layer 1003 and the n-type BiTe thermoelectric material layer 1001 correspond to Regions A and C, respectively. The EDS plots indicate that the interlayer 1005 in this example has a thickness of about 10 μm and contains nickel and at least one constituent of the n-type thermoelectric material (i.e., bismuth, tellurium and/or selenium in this example). Further, the interlayer 1005 acts as a barrier layer such that metal material from the contact layer 1003 is inhibited from diffusing into the thermoelectric layer 1001. As shown in FIG. 10C-10D, for example, Region C, corresponding to the thermoelectric material layer 1001, is substantially free of nickel.

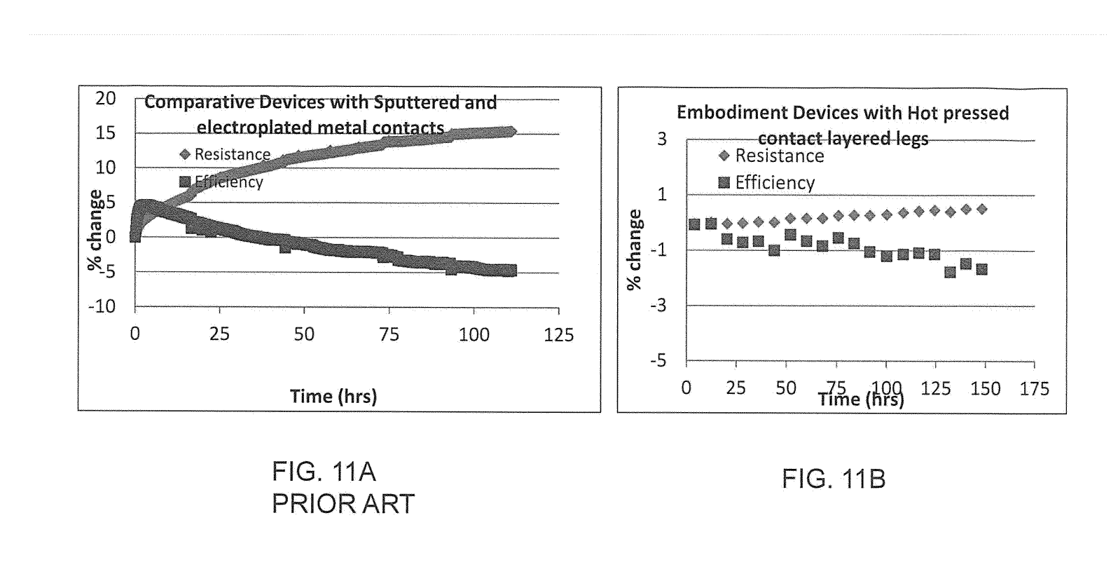

FIGS. 11A and 11B are plots showing the percent change in contact resistance and device (including thermal absorber) efficiency over time for two groups of thermoelectric devices. The first group of devices (Comparative Devices), plotted in FIG. 11A, are BiTe thermoelectric generator devices in which the metal contact layers were provided using conventional sputtering and electroplating. In the Comparative Devices, the contact metal layers include a 20 nm Ti layer formed by sputtering, followed by a 400 nm Ni layer formed by sputtering, and a 3 μm Ni layer formed by electroplating. The second group of devices (Embodiment Devices), plotted in FIG. 11B, are BiTe thermoelectric generator devices that have been formed by hot pressing 300 μm Ni contact metal layers, as described above, but are otherwise identical to the Comparative Devices. As is evident from the plots, the Embodiment Devices exhibit greater stability over time in terms of contact resistance and device efficiency than the Comparative Devices. As shown in FIG. 11B, the contact resistance increased by less than 1% (e.g., 0.1-0.5% over 100-150 hours) and device efficiency decreased by less than 2% (e.g., 1.5 to 1.9% over 100-150 hours).

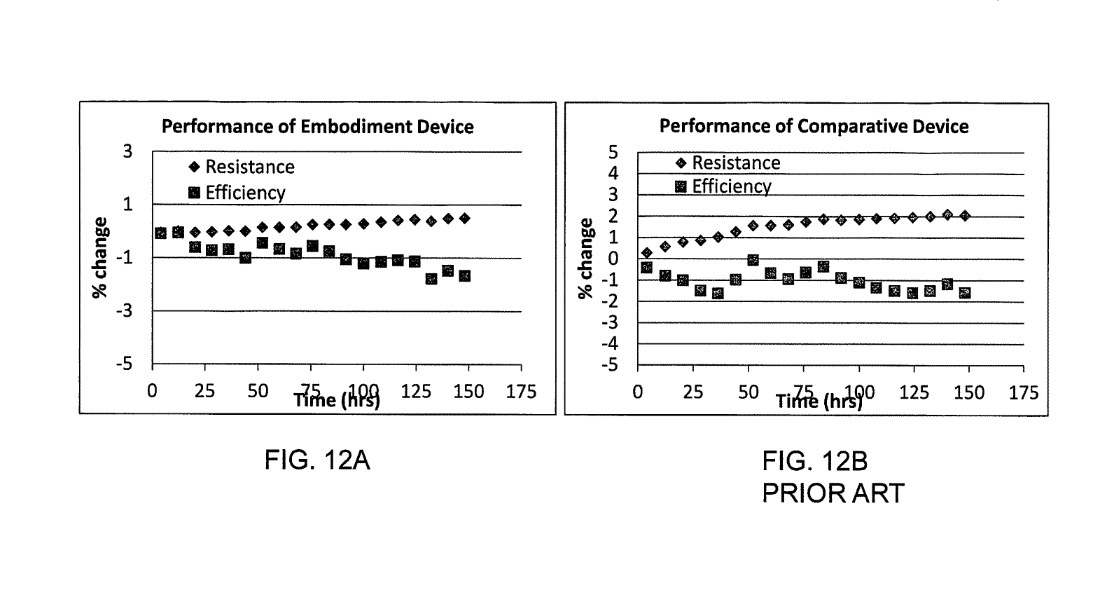

FIGS. 12A and 12B are plots showing the percent change in contact resistance and device efficiency over time for two groups of thermoelectric generator devices: the Embodiment Devices (FIG. 12A, which is the same as FIG. 11B) having contact metal layers formed by hot pressing as described above, and a second group of comparative devices (FIG. 12B). The second group of comparative devices shown in FIG. 12B are commercially-available thermoelectric devices having contact metal layers formed by thermal spray. As seen from the plots, the contact resistance of the Embodiment Devices is more stable than that of the comparative devices, and the Embodiment Devices exhibit similar efficiency as the comparative devices.

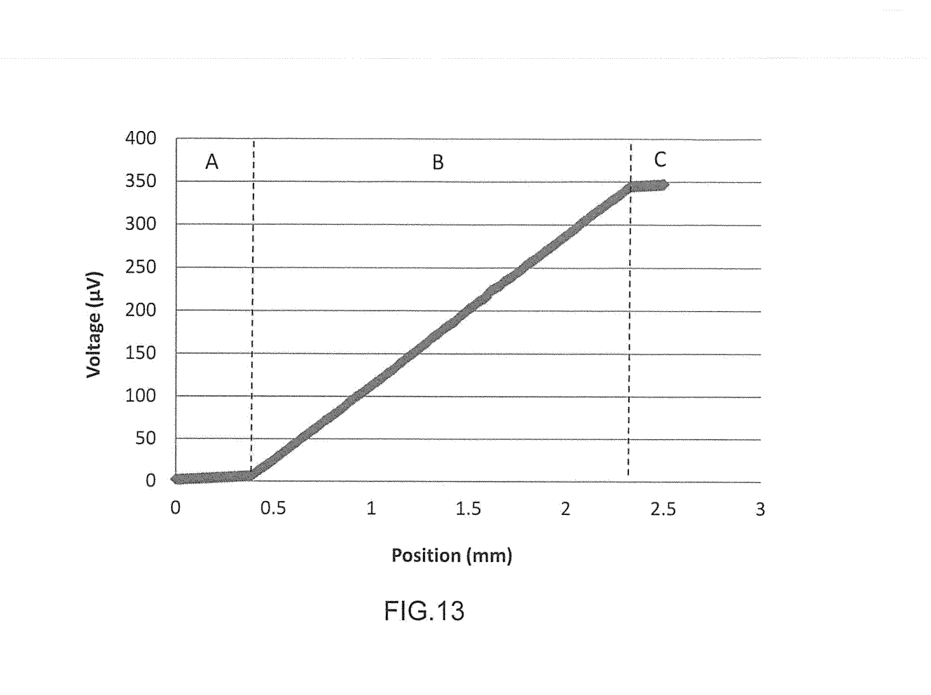

FIG. 13 is a plot of voltage vs. distance for an n-type half-Heusler thermoelectric element having metal contact layers formed by hot pressing. The n-type half-Heusler materials in this example are Hf_{1-x-y}ZrₓTi_{y}NiSn_{1-z}Sb_{z}, where 0≦x≦1.0, 0≦y≦1.0, and z=0.2. The contact layer is titanium. Region A (0 to ˜0.4 mm) corresponds to a first titanium contact layer, Region B (˜0.4 to ˜2.3 mm) corresponds to the n-type half-Heusler layer, and Region C (˜2.3 to ˜2.6 mm) corresponds to the second titanium contact layer. It is noted that the plot of measured voltages (which are proportional to resistance) includes substantially no gap in the transition between Region A and Region B, as well as substantially no gap in the transition between Regions B and C. This indicates that the contact resistance of the device is low (e.g., ˜1 μΩ-cm²). In this example, the tensile strength of the Ti contact layer on the n-type half-Heusler thermoelectric material was ˜30 MPa.

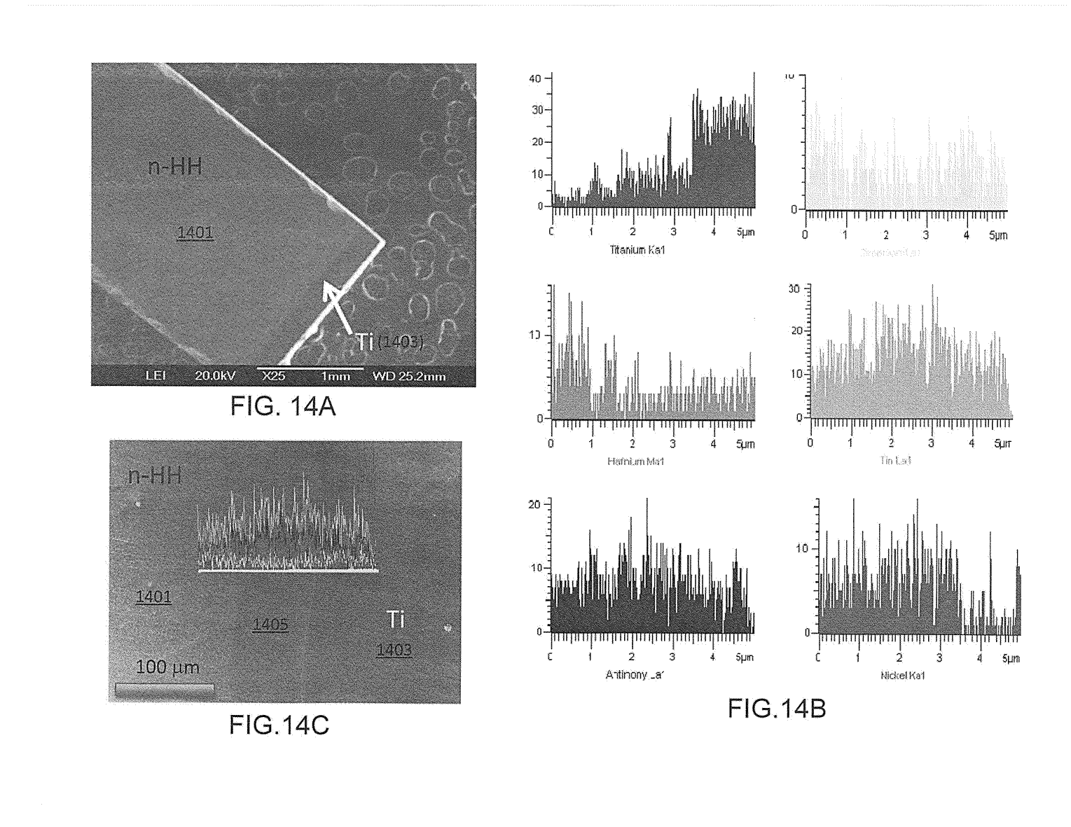

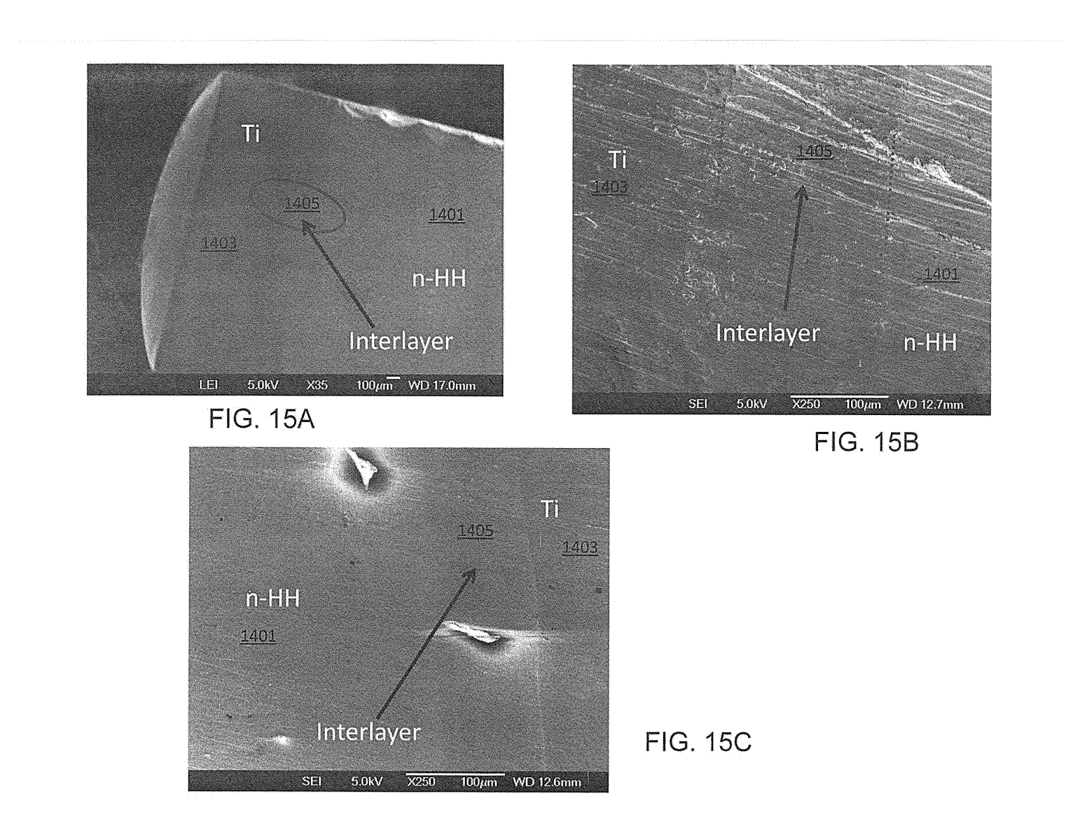

FIG. 14A is a SEM image of an n-type half-Heusler thermoelectric element having titanium contact layers formed by hot pressing, as discussed above. FIG. 14B shows EDS plots for the element, and FIG. 14C is a magnified SEM image of the element with an EDS spectra overlay. FIG. 14C shows the existence of an interlayer 1405 between the Ti contact layer 1403 and the n-type half-Heusler layer 1401. The interlayer 1405 is also evident in the SEM images of FIGS. 15A-15C. The interlayer 1405 in this embodiment has a thickness of around 100 μm.

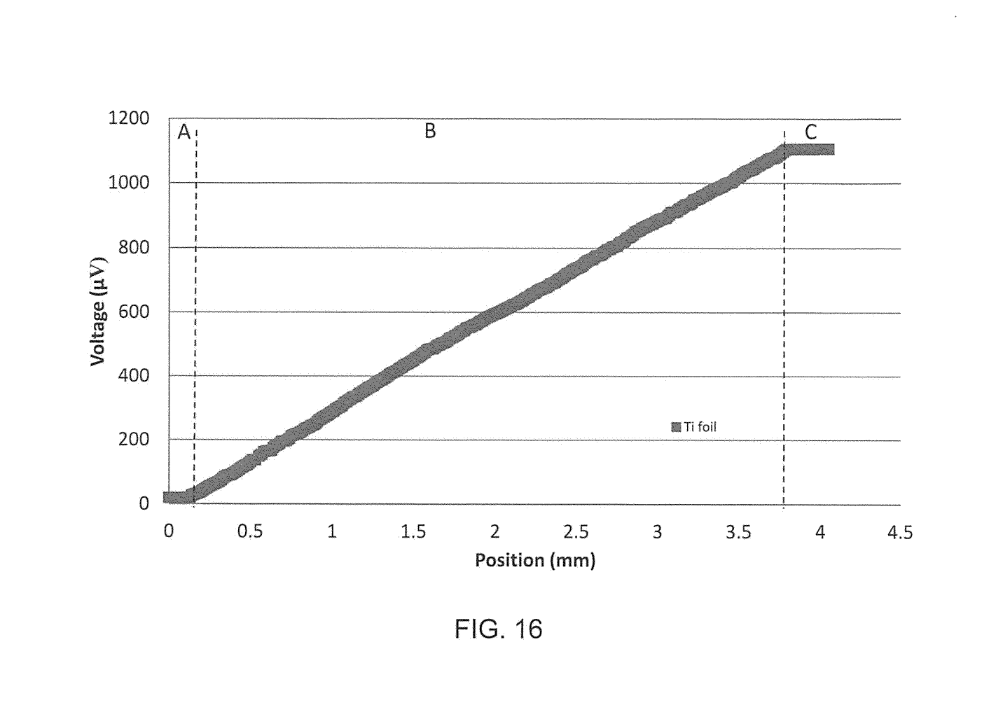

FIG. 16 is a plot of voltage vs. distance for a p-type half-Heusler thermoelectric element having metal contact layers formed by hot pressing. The p-type half-Heusler materials in this example is Hf_{0.5}Zr_{0.5}CoSn_{0.2}Sb_{0.8}. The contact layer is titanium foil that is adhered to the thermoelectric material by hot pressing. Region A (0 to ˜0.2 mm) corresponds to a first titanium contact layer, Region B (˜0.2 to ˜3.8 mm) corresponds to the p-type half-Heusler layer, and Region C (˜3.8 to ˜4.1 mm) corresponds to the second titanium contact layer. It is noted that the plot of measured voltages (which are proportional to resistance) includes substantially no gap in the transition between Region A and Region B, as well as substantially no gap in the transition between Regions B and C. This indicates that the contact resistance of the device is low (e.g., ˜1 μΩ-cm²). In this example, the tensile strength of the Ti contact layer on the p-type half-Heusler thermoelectric material was ˜30 MPa.

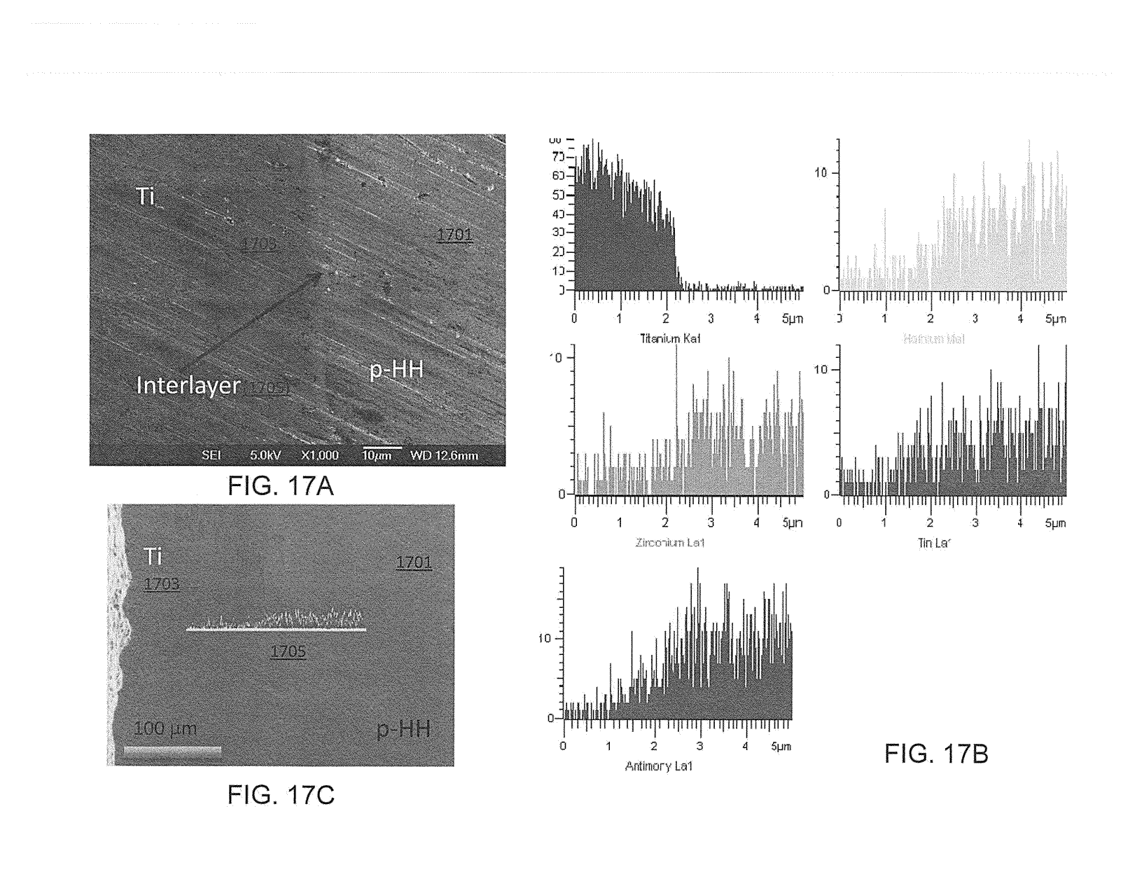

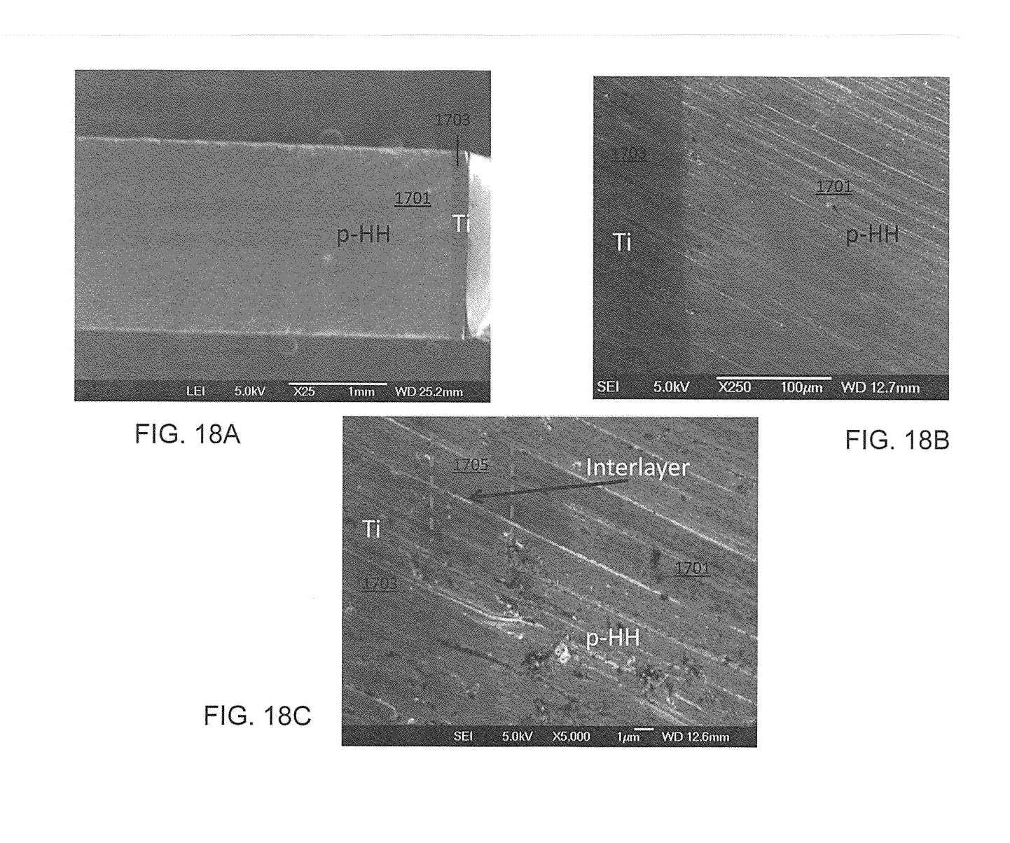

FIG. 17A is a SEM image of a p-type half-Heusler thermoelectric element having titanium contact layers formed by hot pressing, as discussed above. FIG. 17B shows EDS plots for the element, and FIG. 17C is a magnified SEM image of the element with an EDS spectra overlay. FIGS. 17A and 17C show the existence of an interlayer 1705 between the Ti contact layer 1703 and the p-type half-Heusler layer 1701. The interlayer 1705 is also evident in the SEM images of FIGS. 18A-18C. The interlayer 1705 in this embodiment has a thickness of around 5 μm.

The foregoing method descriptions are provided merely as illustrative examples and are not intended to require or imply that the steps of the various embodiments must be performed in the order presented. As will be appreciated by one of skill in the art the order of steps in the foregoing embodiments may be performed in any order. Words such as “thereafter,” “then,” “next,” etc. are not necessarily intended to limit the order of the steps; these words may be used to guide the reader through the description of the methods. Further, any reference to claim elements in the singular, for example, using the articles “a,” “an” or “the” is not to be construed as limiting the element to the singular.

Further, any step or component of any embodiment described herein can be used in any other embodiment.

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A method of fabricating a thermoelectric element, comprising:
forming a solid body comprising thermoelectric material having first dimension of 150 mm or more and a thickness dimension of 5 mm or less; and
dicing the body into a plurality of thermoelectric legs, without cutting along the thickness dimension of the body.

2. The method of claim 1, wherein: the solid body is formed by hot pressing particles of thermoelectric material, and wherein each leg has a length of 0.5-5 mm, a width of 0.5-5 mm, and a thickness of 0.5-5 mm.

3. The method of claim 2, wherein the particles are nano-sized particles.

4. The method of claim 2, wherein the particles are micro-sized particles.

5. The method of claim 2, wherein the solid body is formed by hot pressing a semiconductor thermoelectric material and a metal material to produce a solid body having at least one contact metal layer over a surface of the semiconductor thermoelectric material.

6. The method of claim 1, wherein yield losses from dicing due to edge loss and kerf loss is less than approximately 1%.

7. A solid body comprising thermoelectric material having a first dimension of 150 mm or more and a thickness dimension of 5 mm or less, wherein the solid body is formed by hot pressing particles of thermoelectric material.

8. The solid body of claim 7, wherein the particles are nano-sized particles.

9. The solid body of claim 7, wherein the particles are micro-sized particles.

10. The solid body of claim 7, further comprising at least one contact metal layer over a surface of the thermoelectric material.

11. The solid body of claim 10, wherein the contact metal layer is formed by hot pressing a metal material over a surface of the thermoelectric material.

12. The solid body of claim 11, further comprising an interlayer which comprises the metal material and at least one constituent of the thermoelectric material between the contact metal layer and the thermoelectric material layer.

13. The solid body of claim 12, wherein a thickness of the thermoelectric material layer is 0.5 to 5 mm, a thickness of the contact metal layers is 0.05 to 1 mm, and a thickness of the interlayer is 1 to 100 μm.

14. The solid body of claim 12, further comprising first and second contact metal layers and first and second interlayers between the respective first and second contact metal layers and the thermoelectric material.

15. The solid body of claim 7, wherein the thermoelectric material comprises a bismuth telluride based thermoelectric material.

16. The solid body of claim 7, wherein the thermoelectric material comprises a half-Heusler thermoelectric material.

17. The solid body of claim 7, wherein the hot pressing particles of thermoelectric material comprises simultaneously applying a pressure of 20-200 MPa at a temperature of 200-1500° C. for a period of between 30 seconds and 2 hours.

18. A method of fabricating a thermoelectric element, comprising:
providing a metal material over a surface of a thermoelectric material; and
hot pressing the metal material and the thermoelectric material to form a solid body having a contact metal layer and a thermoelectric material layer.

19. The method of claim 18, further comprising forming an interlayer which comprises the metal material and at least one constituent of the thermoelectric material between the contact metal layer and the thermoelectric material layer during the step of hot pressing.

20. The method of claim 19, wherein a thickness of the thermoelectric material layer is 0.5 to 5 mm, a thickness of the contact metal layers is 0.05 to 1 mm, and a thickness of the interlayer is 1 to 100 μm.
